(19) United States
(12) Patent Application Publication
(10) Pub. No.: US 2023/0105196 A1
(43) Pub. Date: Apr. 6, 2023

(54) DISPLAY DEVICE

(71) Applicant: SHARP KABUSHIKI KAISHA, Sakai City, Osaka (JP)

(72) Inventors: Akira OHSHIMA, Sakai City, Osaka (JP); YASUSHI ASAOKA, Sakai City, Osaka (JP); YOSHIHIRO UETA, Sakai City, Osaka (JP); TAZUKO KITAZAWA, Sakai City, Osaka (JP)

(21) Appl. No.: 17/798,488

(22) PCT Filed: Mar. 2, 2020
(86) PCT No.: PCT/JP2020/008760

§ 371 Date: Aug. 9, 2022

(51) Int. Cl. H01L 27/15

(52) U.S. Cl. CPC H01L 27/156

(57) ABSTRACT

A display device includes a substrate and a pixel provided on the substrate. The pixel includes a light-emitting portion including a plurality of light-emitting elements and configured to generate light, and a light-exiting portion adjacent to the light-emitting portion. The light-exiting portion includes a first light-reflecting portion provided on an incline on the substrate and configured to receive and reflect the light from the light-emitting portion, and an opening configured to emit the light reflected by the first light-reflecting portion to the outside. At least some of the plurality of light-emitting elements are formed by being layered.

### TECHNICAL FIELD

The present invention relates to a display device.

### BACKGROUND ART

In recent years, a self-luminous display device using an electroluminescence (hereinafter “EL”) element employing an EL phenomenon, for example, has been developed as a display device instead of a liquid crystal display device.

The EL element has a configuration in which a light-emitting layer containing a light-emitting material is interposed between two electrodes. Subpixels including red color (R) EL elements, subpixels including green color (G) EL elements, and subpixels including blue color (B) EL elements arrayed on a substrate are selectively made to emit light with desired luminance by use of thin-film transistors (TFTs) to display intended images. Between every set of mutually-adjacent EL elements, a bank (partition) is disposed to define light-emitting regions of the subpixels. The light-emitting layer in each EL element is formed in an opening in the bank by use of a vapor deposition mask. Light generated in the light-emitting layer is extracted outside the display device from the opening of the bank.

In a display device described in PTL 1, a base having a forwardly tapered shape is formed on a substrate, with electrodes and light-emitting layers provided on an inclined face of the base. The light generated by the light-emitting layers is extracted from an opening provided above the base.

### CITATION LIST

### Patent Literature

PTL 1: JP 2015-109190 A (published on Jun. 11, 2015)

### SUMMARY OF INVENTION

### Technical Problem

In a self-luminous display device, some of light generated by the light-emitting layers propagates and disappears in a lateral direction (direction parallel to the electrode) along an interface. Therefore, there is a problem in that about 20% of the light generated by the light-emitting layers is extracted outside the display device, resulting in a poor light extraction efficiency.

Further, in the prior art, there is room for improvement in achieving high luminance, or in the ability to form such pixels at high density while reducing a pixel area and making the pixels smaller.

An aspect of the present invention has been made in view of the problems described above, and an object thereof is to provide a display device that achieves high luminance or is capable of forming pixels at high density while reducing a pixel area and making the pixels smaller.

### Solution to Problem

A display device according to an aspect of the present invention is a display device including a substrate, and a pixel provided on the substrate. The pixel includes a light-emitting portion including a plurality of light-emitting elements and configured to generate light, and a light-exiting portion adjacent to the light-emitting portion. The light-exiting portion includes a first light-reflecting portion provided on an incline on the substrate and configured to receive and reflect the light from the light-emitting portion, and an opening configured to emit the light reflected by the first light-reflecting portion to the outside. At least some of the plurality of light-emitting elements are formed by being layered.

Further, in the display device according to an aspect of the present invention, the light-emitting portion includes a red light-emitting element configured to emit red light, a green light-emitting element configured to emit green light, and a blue light-emitting element configured to emit blue light.

In the display device according to an aspect of the present invention, in the light-emitting portion, the blue light-emitting element has a light-emitting area larger than that of the red light-emitting element and the green light-emitting element.

In the display device according to an aspect of the present invention, each of the plurality of light-emitting elements includes a first electrode, a light-emitting layer, and a second electrode in this order from the substrate side.

In the display device according to an aspect of the present invention, the light-emitting portion includes a light absorption layer in an upper layer overlying the second electrode.

In the display device according to an aspect of the present invention, at least one second light-reflecting portion is provided between the substrate and the first electrode, between the first electrode and the light-emitting layer, between the light-emitting layer and the second electrode, and between the second electrode and the light absorption layer, and some of light generated by the light-emitting layer is reflected by the second light-reflecting portion and guided to the light-exiting portion.

In the display device according to an aspect of the present invention, the second light-reflecting portion has a refractive index lower than that of the light-emitting layer.

In the display device according to an aspect of the present invention, the second light-reflecting portion is constituted by a plurality of layers, the plurality of layers are provided so that a refractive index decreases in order from a layer closest to the light-emitting layer to a layer farthest from the light-emitting layer, and the layer closest to the light-emitting layer has a refractive index lower than that of the light-emitting layer.

In the display device according to an aspect of the present invention, the second light-reflecting portion includes a metal layer formed of a metal material.

In the display device according to an aspect of the present invention, the second light-reflecting portion includes a gas layer formed of a gas.

In the display device according to an aspect of the present invention, the second light-reflecting portion has unevenness on a surface facing the light-emitting layer.

In the display device according to an aspect of the present invention, the light absorption layer has unevenness on a surface on a side opposite to the light-emitting layer.

In the display device according to an aspect of the present invention, the opening has unevenness formed by shaving a waveguide on an opening face.

In the display device according to an aspect of the present invention, the light-exiting portion is disposed surrounding the light-emitting portion.

In the display device according to an aspect of the present invention, the opening does not overlap the light-emitting layer in a plan view.

### Advantageous Effects of Invention

According to an aspect of the present invention, it is possible to provide a display device that achieves high luminance or is capable of forming pixels at high density while reducing a pixel area and making the pixels smaller.

### BRIEF DESCRIPTION OF DRAWINGS

FIG. 1 is a diagram schematically illustrating an example of a configuration of a display device according to a first embodiment of the present invention.

FIG. 2 is a schematic partial plan view of the display device in FIG. 1.

FIG. 3 is a diagram for describing reflection of light in a light-emitting portion of the display device in FIG. 1, and is an enlarged cross-sectional view of a case in which a second light-reflecting portion is a single layer.

FIG. 4 is a diagram for describing the reflection of light in the light-emitting portion of the display device in FIG. 1, and is an enlarged cross-sectional view of a case in which the second light-reflecting portion is multi-layered.

FIG. 5 is a table showing a luminous efficiency, a luminosity factor, and a pixel size of each RGB color in the light-emitting portion of the display device in FIG. 1.

FIG. 6 is a diagram schematically illustrating an example of a configuration of a display device according to a second embodiment of the present invention.

FIG. 7 is a diagram schematically illustrating an example of a configuration of a display device according to a third embodiment of the present invention.

FIG. 8 is a diagram schematically illustrating an example of a configuration of a display device according to a fourth embodiment of the present invention.

FIG. 9 is a diagram schematically illustrating an example of a configuration of a display device according to a fifth embodiment of the present invention.

FIG. 10 is a diagram illustrating a manufacturing method of the display device according to FIG. 9 (step 1).

FIG. 11 is a diagram illustrating the manufacturing method of the display device according to FIG. 9 (step 2).

FIG. 12 is a diagram illustrating the manufacturing method of the display device according to FIG. 9 (step 3).

FIG. 13 is a diagram illustrating the manufacturing method of the display device according to FIG. 9 (step 4).

FIG. 14 is a diagram illustrating the manufacturing method of the display device according to FIG. 9 (step 5).

FIG. 15 is a diagram illustrating the manufacturing method of the display device according to FIG. 9 (step 6).

FIG. 16 is a diagram illustrating the manufacturing method of the display device according to FIG. 9 (step 7).

FIG. 17 is a diagram illustrating the manufacturing method of the display device according to FIG. 9 (step 8).

FIG. 18 is a cross-sectional view of a lower constituent element of a display device according to a modified example.

FIG. 19 is a cross-sectional view of an upper constituent element of the display device according to the modified example.

FIG. 20 is a cross-sectional view of a display device according to a modified example.

### DESCRIPTION OF EMBODIMENTS

Hereinafter, a “lower layer” refers to a layer formed in a process before the layer being compared, and an “upper layer” refers to a layer formed in a process after the layer being compared.

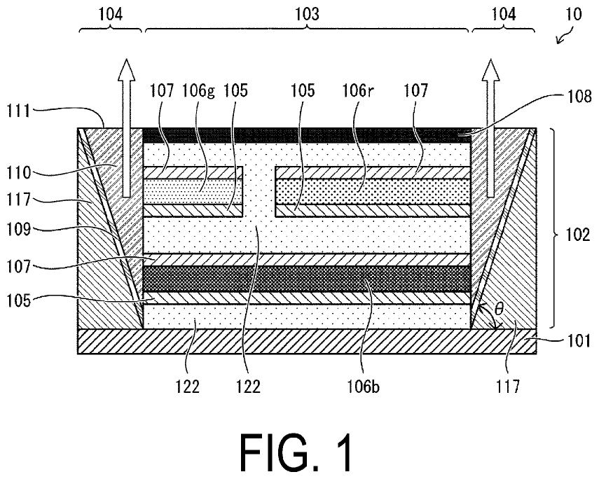

Embodiments of the disclosure will be described with reference to FIG. 1 to FIG. 20 as follows. Hereinafter, for convenience of explanation, components having the same functions as those described in a specific embodiment are appended with the same reference signs, and descriptions thereof may be omitted.

### First Embodiment

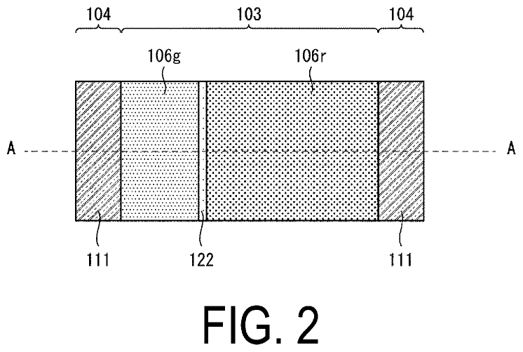

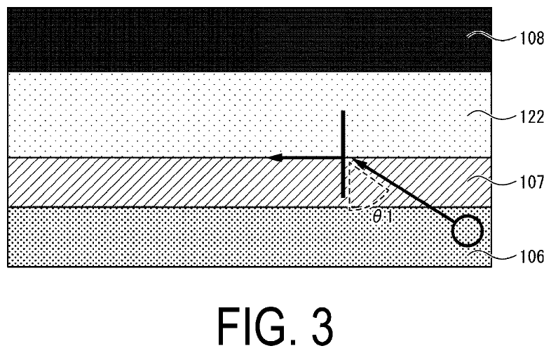

The present embodiment will be described with reference to FIG. 1 to FIG. 5. FIG. 1 is a diagram schematically illustrating an example of a configuration of a display device 10 according to the present embodiment. FIG. 2 is a schematic partial plan view of the display device in FIG. 1, and FIG. 1 is a cross-sectional view taken along line A-A in FIG. 2. FIG. 3 is a diagram for describing reflection of light in a light-emitting portion 103 of the display device 10 in FIG. 1, and is an enlarged cross-sectional view of a case in which a second light-reflecting portion 122 (details described below) is a single layer. The second light-reflecting portion 122 is formed in a layered manner, for example.

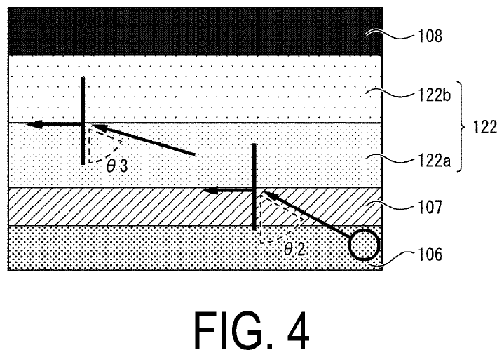

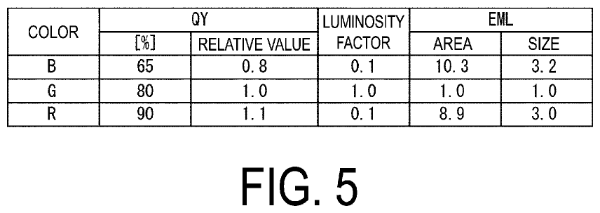

FIG. 4 is a diagram for describing the reflection of light in the light-emitting portion 103 of the display device 10 in FIG. 1, and is an enlarged cross-sectional view of a case in which the second light-reflecting portion 122 (details described below) is multi-layered. FIG. 5 is a table showing a luminous efficiency, a luminosity factor, and a pixel size of each RGB color in the light-emitting portion 103 of the display device 10 in FIG. 1.

As illustrated in FIG. 1, the display device 10 according to the present embodiment is a display device including a substrate 101 and a pixel 102 provided on the substrate 101. The pixel 102 includes the light-emitting portion 103 including a plurality of light-emitting elements and being configured to generate light, and a light-exiting portion 104 adjacent to the light-emitting portion 103.

Further, although two light-exiting portions 104 are illustrated in FIG. 1 and FIG. 2, the number of light-exiting portions 104 is not limited thereto. For example, in a plan view of one pixel, one light-exiting portion may be formed adjacent to one long side of the light-emitting portion 103, or light-exiting portions may be formed on three or more sides of the light-emitting portion 103.

As illustrated in FIG. 1, as an example, the light-emitting portion 103 includes at least a red light-emitting element configured to emit red light (including a light-emitting layer 106r of a red color (R)), a green light-emitting element configured to emit green light (including a light-emitting layer 106g of a green color (G)), and a blue light-emitting element configured to emit blue light (including a light-emitting layer 106b of a blue color (B)). Each of the red light-emitting element, the green light-emitting element, and the blue light-emitting element is a light-emitting element including a light-emitting layer and a pair of electrodes that directly or indirectly sandwich the light-emitting layer. Note that, in this specification, red light refers to light in a wavelength band from 600 nm to 770 nm, green light refers to light in a wavelength band from 495 nm to 590 nm, and blue light refers to light in a wavelength band from 420 nm to 495 nm.

Each of the light-emitting layers may include a function layer such as an electron transport layer (ETL) and a hole transport layer (HTL).

Hereinafter, unless otherwise specified, the light-emitting layer 106r of R, the light-emitting layer 106g of G, and the light-emitting layer 106b of B may be collectively referred to as a light-emitting layer 106.

As illustrated in FIG. 2, the display device 10 is formed with the light-exiting portion 104 (first light-reflecting portion 109, transparent layer (waveguide) 110, and opening 111 described below) adjacent to the light-emitting portion 103. The light-exiting portion 104 may be formed surrounding the light-emitting portion 103. This is preferable in that the light generated by the light-emitting portion 103 is less likely to be repeatedly attenuated, and a reduction in luminous efficiency is likely to be avoided. Further, as illustrated in FIG. 2, in a case in which the light-exiting portion 104 is formed on each side facing the light-emitting portion 103, a size of the pixel 102 is reduced, and a plurality of the pixels 102 are readily formed at high density, making such a configuration preferable.

Further, the light-exiting portion 104 includes the first light-reflecting portion 109 provided on an incline on the substrate 101 and configured to receive and reflect the light from the light-emitting portion 103, and the opening 111 configured to emit the light reflected by the first light-reflecting portion 109 to the outside. Further, as illustrated in FIG. 2, to improve light extraction efficiency, preferably the opening 111 does not overlap the light-emitting layer 106 in a plan view.

As illustrated in FIG. 1, each light-emitting element is formed by layering at least a portion thereof in the light-emitting portion 103. Specifically, in the example illustrated in FIG. 1, the light-emitting layer 106b of B is formed in a lower layer, and the light-emitting layer 106g of G and the light-emitting layer 106r of R are formed in an upper layer.

Further, as illustrated in FIG. 2, in the display device 10, the light-exiting portion 104 may be provided adjacent to two of four sides of the light-emitting portion 103 having a quadrangular shape, and is configured to guide light reflected by the first light-reflecting portion 109 to the opening 111.

A bank 117 is formed between adjacent pixels. The bank 117 includes an inclined face inclined relative to the substrate 101, and the first light-reflecting portion 109 is formed on the inclined face of the bank 117. The first light-reflecting portion 109 is preferably made of a material having high reflectivity, such as a metal such as silver or aluminum, for example. The first light-reflecting portion 109 is formed in a layered manner, for example.

A light absorption layer 108 absorbs external light, and thus can prevent external light reflection. Accordingly, the display device 10 can ensure good visibility even without an anti-reflective film (a circular polarizer composed of a linear polarizer and a ¼λ plate or the like) being provided.

In the display device 10, the light-emitting portion 103 including the light-emitting layer 106 and the light absorption layer 108 is responsible for light emission, and the light-exiting portion 104 including the opening 111 emits light generated by the light-emitting layer 106 to outside of the display device 10 by utilizing reflection. Further, the external light is absorbed by the light absorption layer 108.

As described above, FIG. 2 is a schematic partial plan view of the display device 10. In FIG. 2, the light-emitting layer 106g and the light-emitting layer 106r are illustrated for the purpose of description, but a transparent electrode 107, the second light-reflecting portion 122, and the light absorption layer 108 are formed in upper layers overlying the light-emitting layer 106g and the light-emitting layer 106r.

The light-emitting portion 103 included in each of the pixels of the display device 10 and each light-emitting layer included in the light-emitting portion 103 are formed so as to have a quadrangular shape in a plan view, for example, as illustrated in FIG. 2. Further, the openings 111 are formed adjacent to a pair of sides of the light-emitting portion 103 facing each other, for example.

The light-emitting portion 103 and each light-emitting layer included in the light-emitting portion 103 may be formed in various shapes other than a quadrangular shape, such as a triangular shape. Further, the openings 111 may be formed in various positions other than those illustrated in FIG. 2. For example, the opening 111 may be formed on an entire periphery of the light-emitting portion 103, only on one side including the light-emitting layer 106g and the light-emitting layer 106r, or on three sides or two sides having an L-shape of the light-emitting portion 103.

The display device 10 according to the present embodiment is a structure for laterally extracting light, and can efficiently extract the light generated by the light-emitting layer 106.

Further, because the light-emitting elements are configured to be layered, an area of the light-emitting layer can be widened, making it possible to achieve high luminance. Alternatively, the light-emitting elements may be configured to be layered, making it possible to reduce a pixel area without significantly lowering the luminance of one pixel, achieve an effect such as size reduction, and thus form the pixels at high density.

The display device 10 in the present embodiment overlaps the light-emitting elements (light-emitting layer 106r of R, light-emitting layer 106g of G, and light-emitting layer 106b of B), making it possible to increase an area of the light-emitting element (light-emitting layer 106b of B in the example illustrated in FIG. 1) having low luminous efficiency, and thus achieve a high pixel density without reducing the luminance of the display device 10 overall.

The display device 10 according to the present embodiment will be described in more detail below.

### Substrate 101

The substrate 101 is not particularly limited, and a known support substrate including, for example, an insulating substrate, a barrier layer, or a thin film transistor (TFT) can be used, for example.

The insulating substrate is not particularly limited as long as it has insulating properties. The insulating substrate used may be one of a variety of known insulating substrates, such as transparent substrates such as inorganic material substrates including a glass substrate and a quartz substrate, for example; plastic substrates such as substrates made from polyethylene terephthalate or polyimide resin, for example; and non-transparent substrates such as semiconductor substrates including silicon wafers, substrates obtained by coating an insulating material on a surface of a metal substrate, and substrates obtained by insulation-treating a surface of a metal substrate, for example.

The barrier layer is a layer that inhibits foreign matters such as water and oxygen from entering the TFT layer, and can be formed by a silicon oxide film, a silicon nitride film, or a silicon oxynitride film, or by a layered film of these, formed by chemical vapor deposition (CVD), for example.

The TFT layer includes a semiconductor film, an inorganic insulating film (gate insulating film) in an upper layer overlying the semiconductor film, a gate electrode and a gate wiring line in an upper layer overlying the inorganic insulating film, an inorganic insulating film in an upper layer overlying the gate electrode and the gate wiring line, a capacitance electrode in an upper layer overlying the inorganic insulating film, an inorganic insulating film in an upper layer overlying the capacitance electrode, a source wiring line in an upper layer overlying the inorganic insulating film, and a flattening film (interlayer insulating film) in an upper layer overlying the source wiring line.

The semiconductor film is constituted of, for example, a low-temperature polysilicon (LTPS) or an oxide semiconductor (for example, an In—Ga—Zn—O-based semiconductor), and a transistor (TFT) is configured to include the semiconductor film and the gate electrode. The transistor may have a top gate structure or may have a bottom gate structure.

The gate electrode, the gate wiring line, the capacitance electrode, and the source wiring line are each composed of a single layer film or a layered film of a metal including at least one of aluminum, tungsten, molybdenum, tantalum, chromium, titanium, and copper, for example.

The inorganic insulating film can be formed of, for example, a silicon oxide (SiOx) film or a silicon nitride (SiNx) film, or a layered film of these, formed by CVD. The flattening film may be formed of coatable organic materials such as polyimide and acrylic, for example.

### Pixel 102

As described above, the pixel 102 includes the light-emitting portion 103 and the light-exiting portion 104. The pixel 102 may be an organic light-emitting diode (OLED), or may be an inorganic light-emitting diode, or may be a quantum dot light-emitting diode (QLED). Further, the pixel 102 may be a micro light-emitting diode (LED). A circuit that controls the pixel 102 is formed in the TFT layer of the substrate 101.

### Light-Emitting Portion 103

As illustrated in FIG. 1, in the light-emitting portion 103, the blue light-emitting element has a light-emitting area larger than that of the red light-emitting element and the green light-emitting element. In general, the blue light-emitting element has inferior luminous efficiency compared to those of the red light-emitting element and the green light-emitting element. However, in the pixel 102, layering the blue light-emitting element, the red light-emitting element, and the green light-emitting element vertically widens the area of the light-emitting layer of the blue light-emitting element without narrowing the area of the light-emitting layer of the red light-emitting element and the green light-emitting element, thereby increasing the light emission amount of the blue light-emitting element, and thus is preferred.

Further, as illustrated in FIG. 1, each light-emitting element includes a first electrode 105, the light-emitting layer 106, and the second electrode 107 in this order from the substrate 101 side. Further, in the light-emitting portion 103, the light absorption layer 108 is formed in an upper layer overlying the second electrode 107.

Although only partially illustrated, as illustrated in FIG. 1, the light-emitting layer 106 is disposed so as to be interposed between the first electrode 105 and the second electrode 107.

### Light-Exiting Portion 104

The light-exiting portion 104 includes a region with at least some of the pixel 102 overlapping the opening 111 in a plan view and not covered by the light absorption layer 108, and includes the first light-reflecting portion 109 provided on an incline on the substrate 101, and the opening 111 provided in the light absorption layer 108.

The light-exiting portion 104 may further include the waveguide (transparent layer) 110 provided so as to further guide the light reflected by the first light-reflecting portion 109 to the opening 111, as necessary. Further, although the waveguide 110 and the light-emitting portion 103 are adjacent to each other in FIG. 1, the light-exiting portion 104 may include other optical members provided between the waveguide 110 and the light-emitting portion 103.

### First Electrode 105 and Second Electrode 107

The first electrode 105, which is a lower layer electrode, is formed for each light-emitting element, and is connected to the corresponding TFT via a contact hole (not illustrated) provided in a lower layer underlying the first electrode 105, for example.

The second electrode 107, which is an upper layer electrode, is formed for each light-emitting element, and is connected to a wiring line or the like via a contact hole (not illustrated) provided in an upper layer overlying the second electrode 107, for example.

Further, for example, the first electrodes 105 of each light-emitting element, or the second electrodes 107 of each light-emitting element, or the first electrode 105 of one light-emitting element and the second electrode 107 of another light-emitting element may be electrically connected to each other to form a common electrode.

The first electrode 105 and the second electrode 107 may be transparent electrodes that use a transparent electrode material, or may be reflective electrodes that use a reflective electrode material. At least one of the first electrode 105 and the second electrode 107 is preferably a transparent electrode as such a configuration increases the light extraction efficiency. Here, a refractive index of the transparent electrode is preferably lower than a refractive index of the light-emitting layer 106.

At least one of the first electrode 105 and the second electrode 107 is a transparent electrode having a refractive index lower than that of the light-emitting layer 106, and thus some of the light generated by the light-emitting layer 106 is totally reflected at an interface between the light-emitting layer 106 and the transparent electrode, propagates in the lateral direction, reaches the light-exiting portion 104, and exits from the opening 111.

Furthermore, a refractive index of the second light-reflecting portion 122 is set lower than those of the transparent electrodes 105, 107, and thus the light generated by total reflection at an interface between the transparent electrodes 105, 107 and the second light-reflecting portion 122 is also guided to an end face of the light-emitting layer 106.

The total reflection occurring at the interface between the light-emitting layer 106 and the transparent electrodes 105, 107, or the total reflection occurring at the interface between the transparent electrodes and the second light-reflecting portion 122 has superior reflection efficiency compared to metal reflection, allowing light to be propagated substantially without attenuation, and thus making it possible to increase the light extraction efficiency.

The first electrode 105 serving as the lower layer electrode, and the second electrode 107 serving as the upper layer electrode, serve as a pair of electrodes, with one functioning as an anode electrode and the other functioning as a cathode electrode. The first electrode 105 may be the cathode electrode, and the second electrode 107 may be the anode electrode. Conversely, the first electrode 105 may be the anode electrode, and the second electrode 107 may be the cathode electrode. In a case in which the anode electrode and cathode electrode are reversed, the layering order or carrier mobility (carrier transport properties, that is, hole transport properties and electron transport properties) of each function layer described below are reversed accordingly.

In a case in which the pixel 102 is an OLED, positive holes and electrons recombine inside the light-emitting layer 106 in response to a drive current between the anode electrode and the cathode electrode, and light is emitted when the excitons generated in this manner transition to a ground state.

In a case where the pixel 102 is a QLED, positive holes and electrons recombine inside the light-emitting layer 106 in response to a drive current between the anode electrode and the cathode electrode, and light (fluorescence) is emitted when the excitons generated in this manner transition from the conduction band of the quantum dot to the valence band.

Electrode materials are not particularly limited, and known electrode materials may be employed.

Examples of the transparent electrode material include indium tin oxide (ITO), tin oxide (SnO2), indium zinc oxide (IZO), and gallium-added zinc oxide (GZO).

Examples of the reflective electrode material include a black electrode material such as tantalum (Ta) or carbon (C), Al, Ag, gold (Au), Al—Li alloy, Al-neodymium (Nd) alloy, and Al-silicon (Si) alloy.

### Light-Emitting Layer 106

The light-emitting layer 106 is a layer having a function of emitting light by causing the holes (positive holes) injected from the anode electrode side and the electrons injected from the cathode electrode side to recombine so as to emit light, and utilizes quantum dots, for example, for light emission.

Various known types of light-emitting material may be employed as the material of the light-emitting layer (namely, a light-emitting substance), and the material is not limited to a specific material. A light-emitting material having a high luminous efficiency is preferably employed therefor, such as a low molecular weight fluorescent colorant or a metal complex.

Examples of the light-emitting material include anthracene, naphthalene, indene, phenanthrene, pyrene, naphthacene, triphenylene, perylene, picene, fluoranthene, acephenanthrylene, pentaphene, pentacene, coronene, butadiene, coumarin, acridine, stilbene, and derivatives thereof; a tris(8-quinolinolato)aluminum complex; a bis(benzoquinolinolato) beryllium complex; a tri(dibenzoylmethyl)phenanthroline europium complex; ditoluylvinylbiphenyl; and nanocrystals containing phosphors such as InP and CdSe.

A layer thickness of the light-emitting layer 106 is set as appropriate according to the light-emitting material, is not limited to a specific value, and is, for example, from about several nm to about several hundred nm.

Further, the light-emitting layer 106 may have a single layer configuration or may have a multilayer configuration including a plurality of layers.

### Function Layer

As described above, the light-emitting portion 102 may include further function layers between the first electrode 105 and the light-emitting layer 106 and between the light-emitting layer 106 and the second electrode 107, as necessary.

Typical examples of such a function layer include layers such as a hole injection layer, a hole transport layer, an electron transport layer, and an electron injection layer.

The hole injection layer is a layer including a hole injection material and having the function of increasing the hole injection efficiency from the anode electrode to the light-emitting layer 106. Further, the hole transport layer is a layer including a hole injection material and having the function of increasing the hole transport efficiency to the light-emitting layer 106.

The electron injection layer is a layer including an electron injection and having the function of increasing the electron injection efficiency from the cathode electrode to the light-emitting layer 106. The electron transport layer is a layer including an electron transport material and having the function of increasing the electron transport efficiency to the light-emitting layer 106.

The hole injection layer and the hole transport layer may be formed as mutually independent layers, or may be integrated together as a hole injection-cum-transport layer. Similarly, the electron injection layer and the electron transport layer may be formed as mutually independent layers, or may be integrated together as an electron injection-cum-transport layer.

Only one of the hole injection layer and the hole transport layer may be provided. Similarly, only one of the electron injection layer and the electron transport layer may be provided.

Further, other than the function layer stated above, a carrier block layer, an intermediate layer, or the like may be provided.

Note that the material of these function layers and the like is also not limited, and conventional materials may be employed as each such layers. Further, these function layers and the like are not essential layers, and layer thicknesses thereof are not limited to specific values. Thus, the description thereof is omitted in the present embodiment.

### Light Absorption Layer 108 and Opening 111

The light absorption layer 108 is a layer for absorbing external light and suppressing external light reflection.

Examples of the resin forming the light absorption layer 108 include a pigment-containing resin such as carbon black generally used for a black matrix.

The light absorption layer 108 is formed so as to include the opening 111 on the second electrode 107. Here, a portion where the opening 111 is provided corresponds to the light-exiting portion 104, and the other portion corresponds to the light-emitting portion 103.

The opening 111 may overlap or may not overlap the light-emitting layer 106, which is a lower layer underlying the light absorption layer 108, and the first electrode 105 and the second electrode 107, in a plan view. More preferably, the opening 111 is provided so as not to overlap the light-emitting layer 106, the first electrode 105, and the second electrode 107, in a plan view.

According to this configuration, the light reflected by the first light-reflecting portion 109 can be extracted to the outside from the opening 111 without passing through the light-emitting layer 106, the first electrode 105, and the second electrode 107, which have different refractive indices from each other, thereby making the extraction efficiency even higher.

An area of the opening 111 can be set as appropriate in accordance with the desired light extraction efficiency and suppression effect of the external light reflection.

By adjusting an inclination angle θ of the first light-reflecting portion 109 and an area ratio between the opening 111 and the light-emitting portion 103 in accordance with the size of the light-emitting element and the thickness of the pixel 102, it is possible to suppress the external light reflection without providing an anti-reflective film while ensuring favorable light extraction efficiency.

### First Light-Reflecting Portion 109

The first light-reflecting portion 109 is a layer provided on the substrate 101 that is inclined at the inclination angle θ in the region of the light-exiting portion 104.

The inclination angle θ can be set as appropriate so as to guide the light propagating from the light-emitting portion 103 to the opening 111.

By setting the inclination angle θ to 450 or less, preferably from 30° to 45°, for example, it is possible to extract the light generated by the light-emitting portion 103 more efficiently. On the other hand, by setting the inclination angle θ to greater than 45° for example, it is possible to reduce the area of the opening 111, and thus more reliably suppress the external light reflection. Note that the upper limit of the inclination angle is not particularly limited, but can be exemplified as less than 90°, for example.

Further, the inclined face of the first light-reflecting portion 109 may be constituted by one flat face or a combination of a plurality of flat faces, or may be constituted by one curved face or a combination of a plurality of curved faces, or may be constituted by a combination of one or a plurality of flat faces and one or a plurality of curved faces.

Note that the inclination angle θ refers to the angle at which a line segment connecting both end portions of the inclined face of the first light-reflecting portion 109 intersects the substrate 101 in a side view.

The first light-reflecting portion 109 can be formed of a material having high reflectivity such as, for example, a metal such as silver or aluminum.

### Second Light-Reflecting Portion

The second light-reflecting portion 122 may be formed between each light-emitting element as illustrated in FIG. 1, for example.

However, a quantity and a position of the second light-reflecting portion are not limited thereto. That is, the second light-reflecting portion may be configured to be positioned between at least one of the substrate 101 and the first electrode 105, the first electrode 105 and the light-emitting layer 106b of B, the light-emitting layer 106 and the second electrode 107, and the second electrode 107 and the light absorption layer 108. Further, the second light-reflecting portion may have a single layer configuration, or may have a multilayer configuration formed by layering a plurality of layers.

In one aspect of the present invention, the at least one second light-reflecting portion is preferably a layer formed of a transparent resin as such a configuration increases the light extraction efficiency. Here, the refractive index of the second light-reflecting portion is preferably lower than the refractive index of the light-emitting layer 106.

The following describes, on the basis of FIG. 1 to FIG. 4, the propagation of light generated by the light-emitting layer 106 in a case in which the first electrode 105 and the second electrode 107 are transparent electrodes and the second light-reflecting portion 122 is a layer formed of a transparent resin.

As illustrated (in FIG. 1 in particular), in the display device 10 according to the present embodiment, the light generated by the light-emitting layer 106 is totally reflected at the interface in accordance with the refractive index differences between the layers, propagates in the lateral direction, and reaches the light-exiting portion 104. The light reaching the light-exiting portion 104 is reflected by the inclined face of the first light-reflecting portion 109, and exits from the opening 111 via the waveguide 110.

Here, to achieve total reflection, the first electrode 105, the second electrode 107, and the second light-reflecting portion 122 are preferably layered so that the refractive index decreases from the layer closest to the light-emitting layer 106 toward the layer farthest from the light-emitting layer 106.

For example, the refractive index of the second light-reflecting portion 122 positioned between the first electrode 105 and the substrate 101 is preferably lower than the refractive index of the first electrode 105. Similarly, the refractive index of the second light-reflecting portion 122 positioned between the second electrode 107 and the light absorption layer 108 is preferably lower than the refractive index of the second electrode 107.

With such a configuration, as illustrated in FIG. 3, of the light generated by the light-emitting layer 106, light incident on the interface between the second electrode 107 and the second light-reflecting portion 122 at an angle equal to or greater than a critical angle θ1 is totally reflected at this interface and propagates in the lateral direction.

More specifically, in a preferred aspect of the present embodiment, the refractive index of the light-emitting layer 106 is 2, the second electrode 107 is composed of indium tin oxide having a refractive index of 2, and the second light-reflecting portion 122 is formed of polymethyl methacrylate having a refractive index of 1.5. At this time, the critical angle θ1 is 49°.

Accordingly, of the light generated by the light-emitting layer 106, light incident on the interface between the second electrode 107 and the second light-reflecting portion 122 at an angle equal to or greater than 490 (approximately 46%) is totally reflected at this interface between layers and propagates in the lateral direction.

On the other hand, light incident at an angle of less than 49° travels in the second light-reflecting portion 122, reaches the light absorption layer 108, and is absorbed. In this aspect, approximately 46% of the light generated by the light-emitting layer 106 can be extracted from the opening 111 by total reflection.

Next, on the basis of FIG. 4, the propagation of light generated by the light-emitting layer in a case in which the second light-reflecting portion includes a plurality of layers formed of a transparent resin will be described below.

In a case in which the second light-reflecting portion has a multilayer configuration formed by layering a plurality of layers, the plurality of layers are layered so that the refractive index decreases from the layer closest to the light-emitting layer 106 toward the layer farthest from the light-emitting layer 106, and the refractive index of the layer closest to the light-emitting layer 106 is preferably lower than that of the light-emitting layer 106.

For example, FIG. 4 illustrates a case in which the second light-reflecting portion 122 is formed by two layers of a first layer 122a and a second layer 122b. As illustrated in FIG. 4, the second reflective layer 122 formed between the second electrode 107 and the light absorption layer 108 is formed of the first layer 122a and the second layer 122b from a side closer to the second electrode 107. In this case, a refractive index of the second layer 122b is lower than a refractive index of the first layer 122a, and the refractive index of the first layer 122a is preferably lower than the refractive index of the second electrode 107.

With such a configuration, of the light generated by the light-emitting layer 106, light incident on an interface between the second electrode 107 and the first layer 122a at an angle equal to or greater than a critical angle θ2 is totally reflected at this interface and propagates in the lateral direction. Further, at an interface between the first layer 122a and the second layer 122b, light incident at an angle equal to or greater than a critical angle θ3 is totally reflected at this interface and propagates in the lateral direction.

More specifically, in a preferred aspect of the present embodiment, the refractive index of the light-emitting layer 106 is 2, the second electrode 107 is composed of indium tin oxide having a refractive index of 2, the first layer 122a is formed of polymethyl methacrylate having a refractive index of 1.7, and the second layer 122b is formed of a polymethyl methacrylate having a refractive index of 1.5. At this time, the critical angle θ2 is 58°, and the critical angle θ3 is 62°.

Accordingly, of the light generated by the light-emitting layer 106, light incident on the interface between the second electrode 107 and the first layer 122a at an angle equal to or greater than 580 (approximately 35%) is totally reflected at the interface between the layers and propagates in the lateral direction.

On the other hand, light incident at an angle of less than 58° travels in the first layer 122a and reaches the interface with the second layer 122b. Here, the light incident on the interface at an angle of 62° or greater (approximately 20%) is totally reflected at the interface between the layers and propagates in the lateral direction. In this aspect, approximately 55% of the light generated by the light-emitting layer 106 can be guided to the light-exiting portion 104 by total reflection.

By increasing the number of layers of the second light-reflecting portion 122, it is possible to further enhance the light extraction efficiency.

The second light-reflecting portion 122 may be formed of a plurality of layers throughout the light-emitting portion 103, or a plurality of layers may be formed in a portion of the light-emitting portion 103. The number of layers of the second light-reflecting portion 122 may be different in a portion of the light-emitting portion 103, or the materials constituting each layer may be different.

### Luminous Efficiency, Luminosity Factor, and Pixel Size of Each RGB Color

In FIG. 5, each numerical value is based on G. More strictly, external quantum efficiency (EQE) is used as the luminous efficiency instead of quantum yield (QY). Further, the pixel area is proportional to 1/(luminous efficiency×luminosity factor).

On the basis of FIG. 5, by changing a pixel projection area of each color using the luminous efficiency and the luminosity factor, it is possible to obtain the same luminous flux with the same flowing current. Further, by aligning the current (luminous flux) characteristics, the R, G, and B driving circuits and driving algorithms can be made common and simplified.

Furthermore, by changing the pixel area, it is possible to accommodate the R and G light-emitting elements in the B light-emitting element area, and only layer the two layers of the light-emitting layer 106b of B and the light-emitting layers 106r and 106g of R and G.

### Second Embodiment

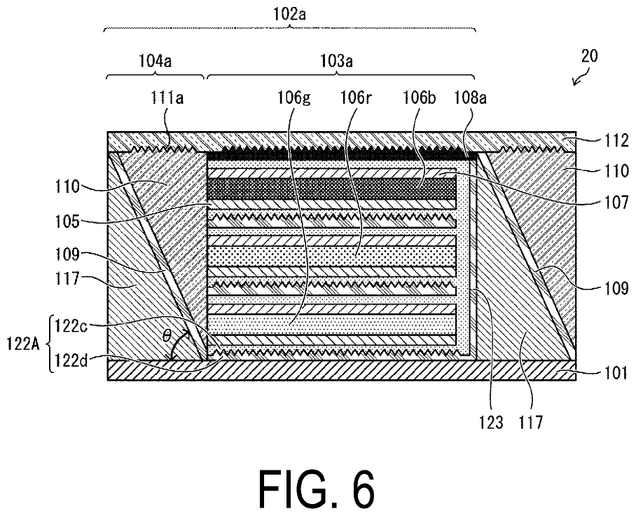

A second embodiment of the present invention will now be described with reference to FIG. 6.

FIG. 6 is a diagram schematically illustrating an example of a configuration of a display device 20 according to the present embodiment. The display device 20 includes a pixel 102a. The pixel 102a includes a light-emitting portion 103a including a plurality of light-emitting elements and configured to generate light, and a light-exiting portion 104a adjacent to the light-emitting portion 103a. The light-emitting portion 103a includes a second light-reflecting portion 122A including a first layer 122c and a second layer 122d.

As illustrated in FIG. 6, the display device 20 according to the present embodiment differs from the display device of the first embodiment mainly in that, in one pixel, the light-exiting portion 104a is only on one side of the light-emitting portion 103a, the light-emitting layer 106g of G, the light-emitting layer 106r of R, and the light-emitting layer 106b of B are formed in this order from a lower layer to an upper layer, the second layer 122d having high reflectivity is formed, and unevenness is formed on the second layer 122d, a light absorption layer 108a, and an opening 111a. Other matters are as described in the first embodiment.

In the present embodiment, as illustrated in FIG. 6, a transparent substrate 112 may be layered so as to cover the pixel 102a. The transparent substrate 112, as a protection layer, prevents oxygen and moisture from entering the pixel 102a from the outside.

In FIG. 6, in one pixel 102a, the light-exiting portion 104a is formed only on one side of the light-emitting portion 103a (left side of the light-emitting portion 103a in FIG. 6), and the light-exiting portion 104a is not formed on the other side of the light-emitting portion 103a (right side of the light-emitting portion 103a in FIG. 6). In FIG. 6, a third light-reflecting portion 123 is provided on the right side of the light-emitting portion 103a where the light-exiting portion 104a is not formed, light incident on the third light-reflecting portion 123 is reflected toward the light-emitting layer side, and light is returned to the light-exiting portion 104a side.

In the display device 20, the first layer 122c of the second light-reflecting portion 122A is formed in a lower layer underlying the first electrode 105 of each light-emitting element, and the second layer 122d is formed in a lower layer underlying each first layer 122c. The second layer 122d can be formed of a metal, for example. Even in a case in which the second layer 122d is formed of a metal having electrical conductivity, leakage between electrodes can be prevented as long as the transparent layer 110 and the first layer 122c adjacent to the second layer 122d have no electrical conductivity.

Each second layer 122d may be provided with unevenness on a surface facing the light-emitting layer 106. With the second layer 122d provided with unevenness on the surface facing the light-emitting layer 106, light generated perpendicular to a light-emitting face of the light-emitting layer 106 can be reflected in an obliquely lateral direction. This makes it possible to increase the light that can be totally reflected in each light-emitting element.

The second layer 122d having such unevenness can be formed by, for example, providing a concave-convex structure on the underlayer by using a nanoprint technique and then vapor-depositing a reflective film of a metal thereon.

Further, the light absorption layer 108a is provided with unevenness on a surface on a side opposite to the light-emitting layer 106. By forming unevenness on the light absorption layer 108a, it is possible to scatter the external light and suppress external light reflection.

Further, such unevenness can be formed by, for example, shaving a surface of the light absorption layer 108a.

Further, unevenness is formed on an opening face of the opening 111a. By forming unevenness on the opening 111a, it is possible to diffuse the emitted light and widen a viewing angle. Such unevenness can be formed by, for example, shaving a surface of the waveguide 110.

In the display device 20 according to the second embodiment, as in the display device 10 according to first embodiment, total reflection can be utilized to increase the light extraction efficiency and, by scattering the external light, external light reflection can be suppressed to widen the viewing angle.

### Third Embodiment

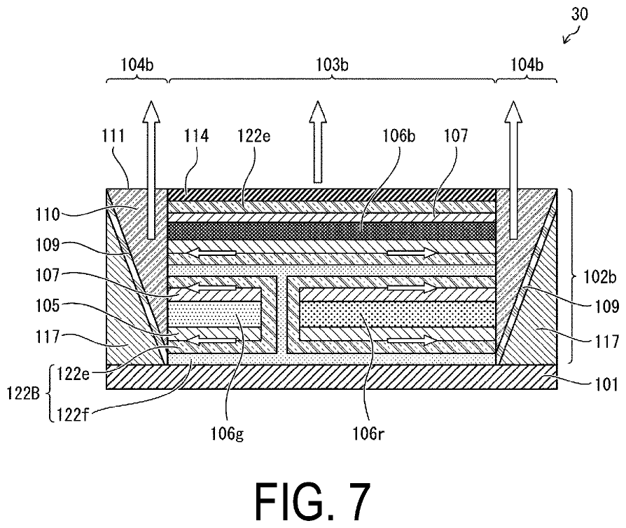

A third embodiment of the present invention will now be described with reference to FIG. 7.

FIG. 7 is a diagram schematically illustrating an example of a configuration of a display device 30 according to the present embodiment. The display device 30 includes a pixel 102b. The pixel 102b includes a light-emitting portion 103b including a plurality of light-emitting elements to generate light, and a light-exiting portion 104b adjacent to the light-emitting portion 103b. The light-emitting portion 103b includes a second light-reflecting portion 122B including a first layer 122e and a second layer 122f. The second layer 122f can be formed of a metal material having high reflectivity such as silver or aluminum, for example.

As illustrated in FIG. 7, the display device 30 according to the present embodiment mainly differs from the display device of the first embodiment in being provided with an anti-reflective film 114 as in the prior art for the prevention of external light reflection instead of the light absorption layer, and in that light is extracted not only laterally but also in the perpendicular direction. The other matters are as described in the first embodiment.

In the display device 30, light emitted from the light-emitting layer (light-emitting layer 106b in FIG. 7) of the light-emitting element formed in the uppermost layer is emitted to the outside via the opening 111, and is emitted to the outside via the anti-reflective film 114 even from the side on which the second electrode 107 is formed.

In the display device 30, light that travels in the perpendicular direction from the light-emitting layer or the like and is thus not totally reflected and is less likely to be guided to the light-exiting portion 104b can be removed to the outside via the anti-reflective film 114. Further, the anti-reflective film 114 can prevent external light reflection.

In the display device 30 according to the third embodiment, the same effects as those of the display device 10 according to the first embodiment can be achieved and, in addition, the light of the light-emitting layer 106b of B generated perpendicular to the light-emitting face can be output as is.

### Fourth Embodiment

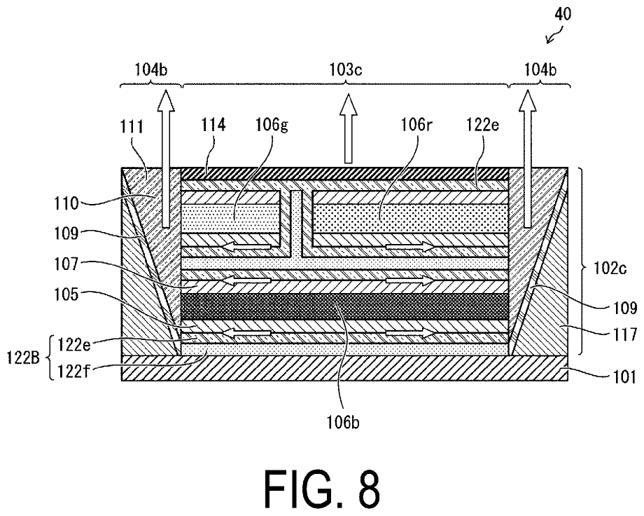

A fourth embodiment of the present invention will now be described with reference to FIG. 8.

FIG. 8 is a diagram schematically illustrating an example of a configuration of a display device 40 according to the present embodiment. The display device 40 includes a pixel 102c. The pixel 102c includes a light-emitting portion 103c including a plurality of light-emitting elements to generate light, and the light-exiting portion 104b adjacent to the light-emitting portion 103c.

The display device 40 includes the light-emitting portion 103c in which the vertical relationship between the light-emitting element including the light-emitting layer 106b, the light-emitting element including the light-emitting layer 106g, and the light-emitting element including the light-emitting layer 106r in the light-emitting portion 103b of the display device 30 of the third embodiment is reversed.

In the display device 40, light emitted from the light-emitting layers (light-emitting layer 106g and light-emitting layer 106r in FIG. 8) of the light-emitting elements formed in the uppermost layer is emitted to the outside via the opening 111, and is emitted to the outside via the anti-reflective film 114 even from the side where the second electrode 107 is formed.

In the display device 40 according to the fourth embodiment, as in the display device 10 according to the first embodiment, total reflection can be utilized to increase the light extraction efficiency, and the light generated vertically above the light-emitting face from the light-emitting layer 106g of G and the light-emitting layer 106r of R can be output to the outside as is.

### Fifth Embodiment

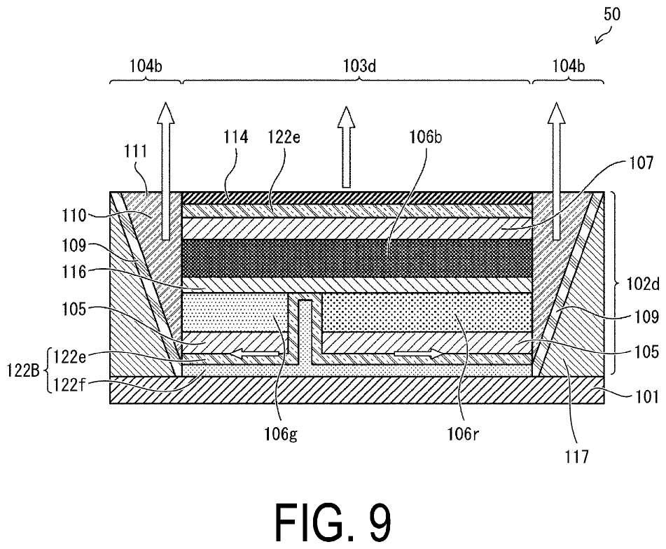

A fifth embodiment of the present invention will now be described with reference to FIG. 9.

FIG. 9 is a diagram schematically illustrating an example of a configuration of a display device 50 according to the present embodiment. The display device 50 includes a pixel 102d. The pixel 102d includes a light-emitting portion 103d including a plurality of light-emitting elements to generate light, and the light-exiting portion 104b adjacent to the light-emitting portion 103d.

As illustrated in FIG. 9, the display device 50 according to the present embodiment mainly differs from the display device of the first embodiment in that the anti-reflective film 114 for the prevention of external light reflection is provided instead of the light absorption layer, and a common electrode 116 is formed that is commonly used by the light-emitting elements formed in a lower layer and the light-emitting elements formed in an upper layer.

Specifically, the common electrode 116 is formed between the light-emitting layer 106b of B formed in an upper layer and the light-emitting layer 106g of G as well as the light-emitting layer 106r of R formed in a lower layer. The common electrode 116 serves as the first electrode of the light-emitting element including the light-emitting layer 106b, and also serves as the second electrode of the light-emitting element including the light-emitting layer 106g and the light-emitting element including the light-emitting layer 106g. According to this configuration, the electrode required for each color in the conventional layered structure is common to all colors, and thus the layered structure can be simplified. The common electrode 116 may be a transparent electrode or a metal electrode, or a metal electrode may be interposed between transparent electrodes.

### Material of Second Reflective Layer

The second light-reflecting portion may be formed of any material capable of reflecting light at an interface with the adjacent layer. Examples of such materials include transparent resins such as polymethyl methacrylate having various refractive indices. The second light-reflecting portion may be a metal layer formed of a metal material such as silver or aluminum. The second light-reflecting portion may be a gas layer formed by a gas such as the atmosphere.

For example, the second light-reflecting portion may be a layer formed of a transparent resin, a metal layer, a gas layer, or a combination of these.

However, in a case in which the second light-reflecting portion is between the first electrode 105 and the light-emitting layer 106b of B and/or between the light-emitting layer 106b of B and the second electrode 107, the second light-reflecting portion is formed of a material having electrical conductivity.

In a preferred aspect of the present invention, the second light-reflecting portion may have a multilayer configuration including, for example, a transparent layer made of a transparent resin positioned on the light-emitting layer 106b of B side and a metal layer positioned on the side opposite to the light-emitting layer 106b of B.

Note that the various electrodes and the banks (partitions) can use materials commonly used in OLEDs and QLEDs.

The display device 50 according to the fifth embodiment can also achieve the same effects as those of the display device 10 according to the first embodiment.

### Manufacturing Process of Display Device

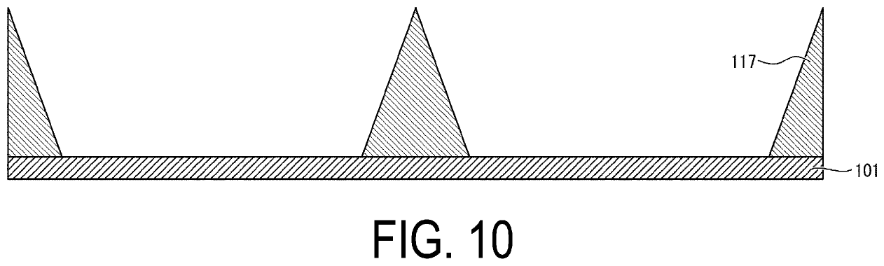

FIG. 10 to FIG. 17 are diagrams illustrating a manufacturing process of the display device 50 according to the present embodiment. Hereinafter, the manufacturing process of the display device 50 according to the present embodiment will be described in detail.

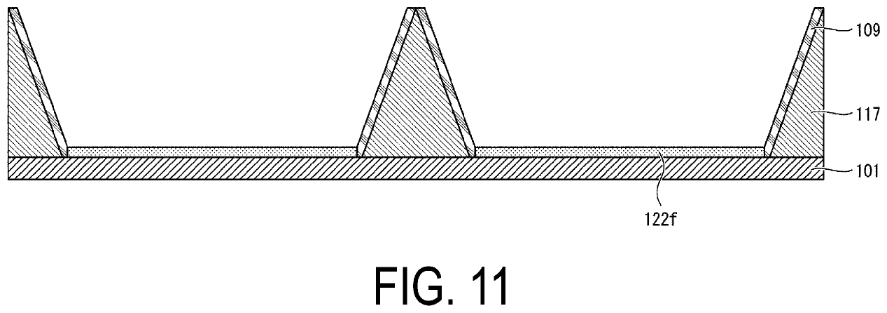

First, as illustrated in FIG. 10, the banks (partitions) 117 having a forward taper are formed by an insulating material on the substrate 101. Subsequently, as illustrated in FIG. 11, the first light-reflecting portion 109 and the second layer 122f of the second light-reflecting portion 122B are formed of a metal, for example. The first light-reflecting portion 109 and the second layer 122f may be formed simultaneously by vapor deposition or another method using the same material, or may be formed separately by different methods using different materials.

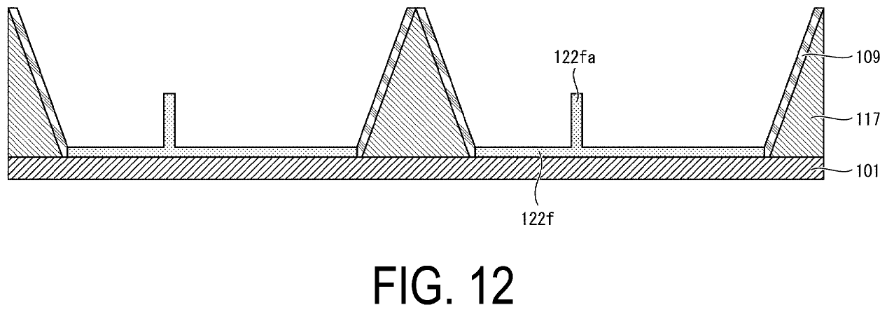

Subsequently, as illustrated in FIG. 12, the second layer 122fa, which is part of the second layer 122f, is formed of a metal, for example. The second layer 122fa is part of the second light-reflecting portion 122B formed between the light-emitting element including the light-emitting layer 106g and the light-emitting element including the light-emitting layer 106g. The second layer 122fa of the second light-reflecting portion 122B is formed by vapor deposition, for example.

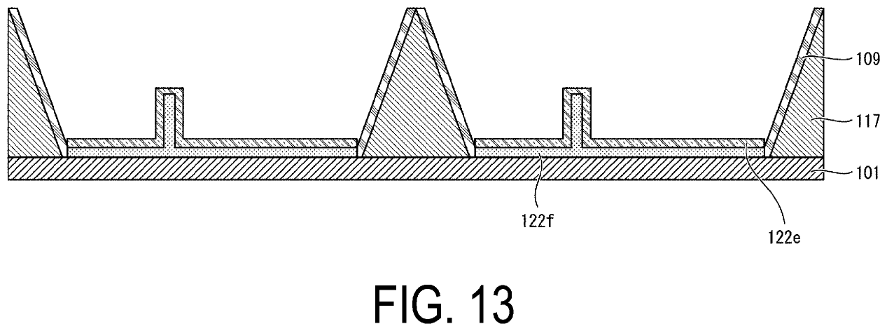

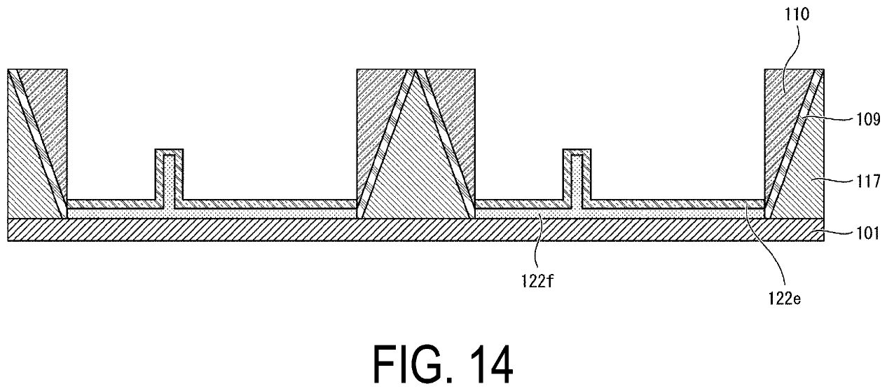

Subsequently, as illustrated in FIG. 13, the first layer 122e is formed in an upper layer overlying the second layer 122f. Subsequently, as illustrated in FIG. 14, the transparent layer (waveguide) 110 is formed in an upper layer overlying the first light-reflecting portion 109. The transparent layer (waveguide) 110 can include a material having light curing properties, and can be formed by exposure and development, for example.

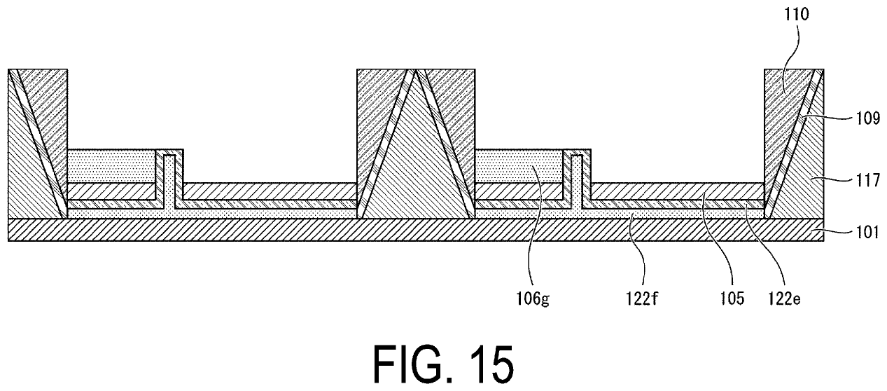

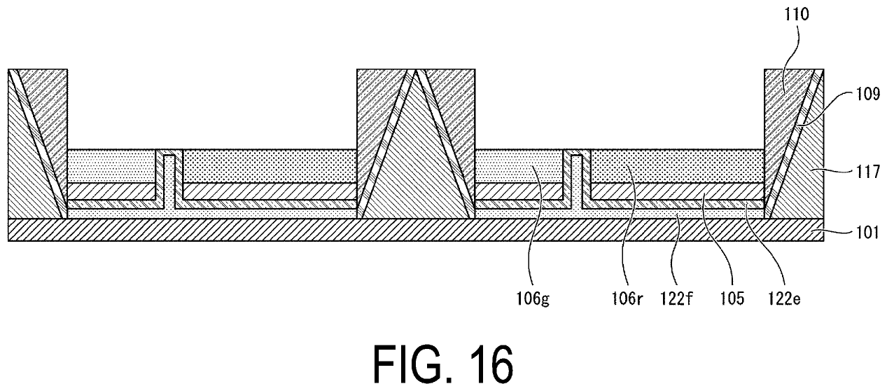

Subsequently, as illustrated in FIG. 15, the first electrode 105 and the light-emitting layer 106g of G are formed in upper layers overlying the second light-reflecting portion 122B, in this order. Subsequently, as illustrated in FIG. 16, the light-emitting layer 106r of R is formed in the same layer as that of the light-emitting layer 106g of G.

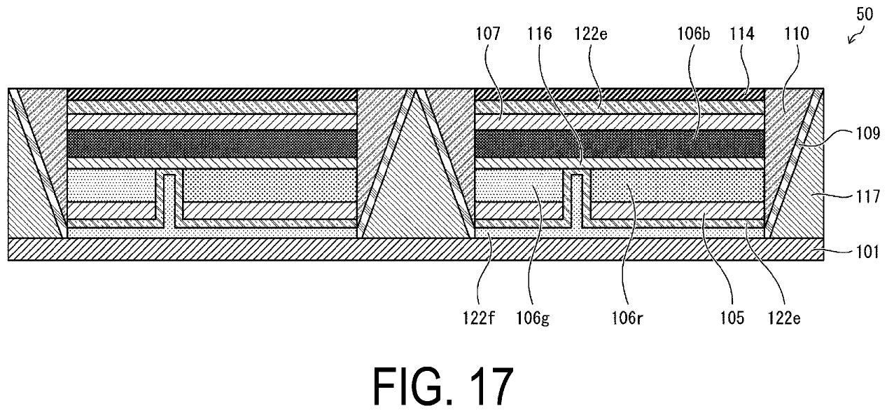

Lastly, as illustrated in FIG. 17, the common electrode 116, the light-emitting layer 106b of B, the second electrode 107, the first layer 122e of the second light-reflecting portion 122B, and the anti-reflective film 114 are formed in this order in upper layers overlying the light-emitting layer 106g of G and the light-emitting layer 106r of R.

Further, in the example of FIG. 17, two display devices 50 are illustrated.

By the process described above, the display device 50 according to the present embodiment is obtained.

### Modified Example

As described above, the second light-reflecting portion may be partially formed as a gas layer constituted by a gas. In the following, a method for manufacturing a display device 60, in which a gas layer is formed, will be described.

When formed, the gas layer can be fabricated by, for example, separately creating an upper constituent element and a lower constituent element and then combining the upper constituent element and the lower constituent element.

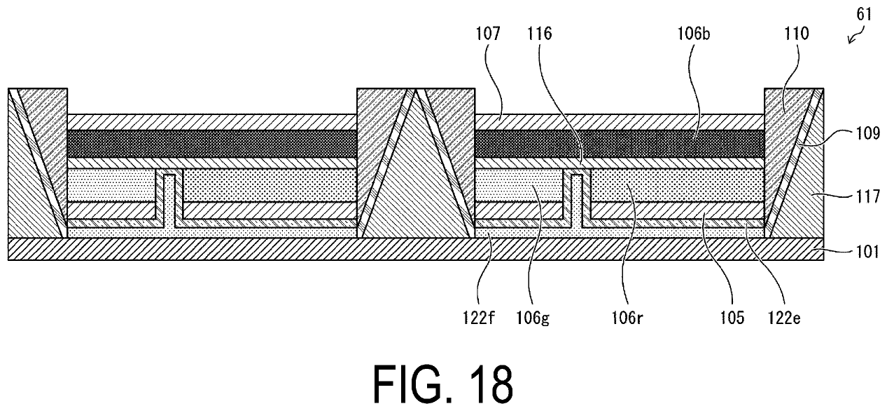

FIG. 18 is a cross-sectional view of a lower constituent element 61 of the display device 60. The lower constituent element 61 can be formed by a method similar to that from FIG. 10 to formation of the second electrode 107 in FIG. 17.

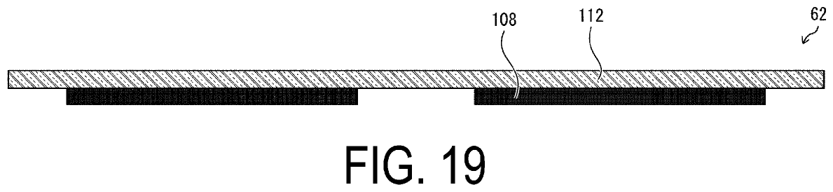

FIG. 19 is a cross-sectional view of an upper constituent element 62 of the display device 60. The upper constituent element 62 is fabricated by forming the light absorption layer 108 on a lower face of the transparent substrate 112.

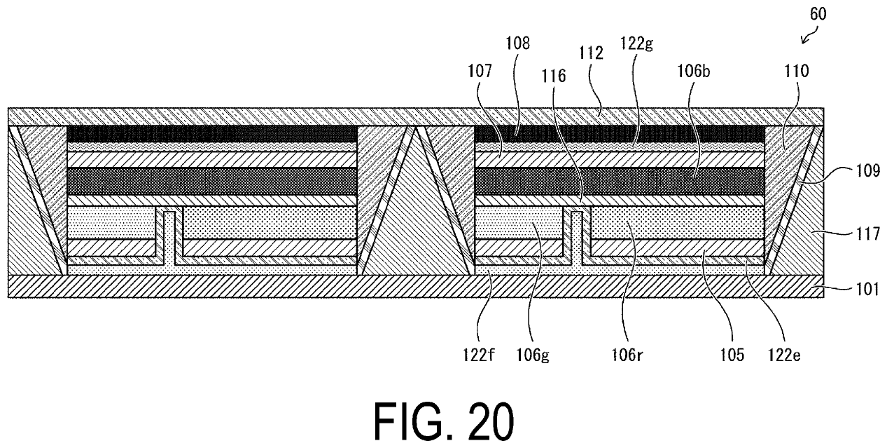

FIG. 20 is a cross-sectional view of the display device 60. In FIG. 20, two display devices 60 are illustrated. The second light-reflecting portion of the display device 60 is constituted by the first layer 122e, the second layer 122f, and a third layer 122g. The display device 60 is formed by bonding the upper constituent element 62 on the lower constituent element 61. This bond is bonded so that a space is formed between the second electrode 107 and the light absorption layer 108. In the display device 60, the space between the second electrode 107 and the light absorption layer 108 is a gas layer, and this portion is the third layer 122g of the second light-reflecting portion.

### Supplement

### First Aspect

A display device includes a substrate, and a pixel provided on the substrate. The pixel includes a light-emitting portion including a plurality of light-emitting elements to generate light, and a light-exiting portion adjacent to the light-emitting portion. The light-exiting portion includes a first light-reflecting portion provided on an incline on the substrate and configured to receive and reflect the light from the light-emitting portion, and an opening configured to emit the light reflected by the first light-reflecting portion to the outside. At least some of the plurality of light-emitting elements are formed by being layered.

### Second Aspect

In the display device according to the first aspect, the light-emitting portion includes a red light-emitting element configured to emit red light, a green light-emitting element configured to emit green light, and a blue light-emitting element configured to emit blue light, for example.

### Third Aspect

In the display device according to the second aspect, in the light-emitting portion, the blue light-emitting element has a light-emitting area larger than that of the red light-emitting element and the green light-emitting element, for example.

### Fourth Aspect

In the display device according to any one of the first to third aspects, each of the plurality of light-emitting elements includes a first electrode, a light-emitting layer, and a second electrode in this order from the substrate side, for example.

### Fifth Aspect

In the display device according to the fourth aspect, the light-emitting portion includes a light absorption layer in an upper layer overlying the second electrode, for example.

### Sixth Aspect

In the display device according to the fifth aspect, at least one second light-reflecting portion is provided between the substrate and the first electrode, between the first electrode and the light-emitting layer, between the light-emitting layer and the second electrode, and between the second electrode and the light absorption layer, and some of light generated by the light-emitting layer is reflected by the second light-reflecting portion and guided to the light-exiting portion, for example.

### Seventh Aspect

In the display device according to the sixth aspect, the second light-reflecting portion has a refractive index lower than that of the light-emitting layer, for example.

### Eighth Aspect

In the display device according to the sixth aspect, the second light-reflecting portion is constituted by a plurality of layers, the plurality of layers are provided so that a refractive index decreases in order from a layer closest to the light-emitting layer to a layer farthest from the light-emitting layer, and the layer closest to the light-emitting layer has a refractive index lower than that of the light-emitting layer, for example.

### Ninth Aspect

In the display device according to any one of the sixth to eighth aspects, the second light-reflecting portion includes a metal layer formed of a metal material, for example.

### Tenth Aspect

In the display device according to any one of the sixth to ninth aspects, the second light-reflecting portion includes a gas layer formed of a gas, for example.

### Eleventh Aspect

In the display device according to any one of the sixth to tenth aspects, the second light-reflecting portion has unevenness on a surface facing the light-emitting layer, for example.

### Twelfth Aspect

In the display device according to any one of the sixth to eleventh aspects, the light absorption layer has unevenness on a surface on a side opposite to the light-emitting layer, for example.

### Thirteenth Aspect

In the display device according to any one of the first to twelfth aspects, the opening has unevenness formed by shaving a waveguide on an opening face, for example.

### Fourteenth Aspect

In the display device according to any one of the first to thirteenth aspects, the light-exiting portion is disposed surrounding the light-emitting portion, for example.

### Fifteenth Aspect

In the display device according to any one of the fourth to twelfth aspects, the opening does not overlap the light-emitting layer in a plan view, for example.

### Additional Items

The present invention is not limited to the embodiments described above, and embodiments obtained by appropriately combining technical approaches disclosed in the different embodiments also fall within the technical scope of the present invention. Furthermore, novel technical features can be formed by combining the technical approaches disclosed in each of the embodiments.

The display device according to the present embodiment is not particularly limited as long as the display device is a display panel provided with display elements such as light-emitting elements. The display element is a display element in which luminance and transmittance are controlled by an electric current, and examples of the electric current-controlled display element include an organic electro-luminescence (EL) display provided with an organic light-emitting diode (OLED), an EL display such as an inorganic EL display provided with an inorganic light-emitting diode, and a quantum dot light-emitting diode (QLED) display provided with a QLED.

### REFERENCE SIGNS LIST

10, 20, 30, 40, 50, 60 Display device
61 Lower constituent element
62 Upper constituent element
101 Substrate
102, 102a, 102b, 102c, 102d Pixel
103, 103a, 103b, 103c, 103d Light-emitting portion
104, 104a, 104b Light-exiting portion
105 First electrode (transparent electrode)
106 Light-emitting layer
106r Light-emitting layer of R
106g Light-emitting layer of G
106b Light-emitting layer of B
107 Second electrode (transparent electrode)
108, 108a Light absorption layer
109 First light-reflecting portion
110 Transparent layer (waveguide)
111 Opening
112 Transparent substrate
114 Anti-reflective film
116 Common electrode
117 Bank
122, 122A, 122B Second light-reflecting portion
122a, 122c, 122e First layer
122b, 122d, 122f, 122fa Second layer
122g Third layer

1. A display device comprising:
a substrate; and
a pixel provided on the substrate,
wherein the pixel includes
a light-emitting portion including a plurality of light-emitting elements and configured to generate light, and
a light-exiting portion adjacent to the light-emitting portion,
the light-exiting portion includes
a first light-reflecting portion provided on an incline on the substrate and configured to receive and reflect the light from the light-emitting portion, and
an opening configured to emit the light reflected by the first light-reflecting portion to the outside, and
at least some of the plurality of light-emitting elements are formed by being layered,
wherein the light-emitting portion includes
a red light-emitting element configured to emit red light,
a green light-emitting element configured to emit green light, and
a blue light-emitting element configured to emit blue light,
wherein, in the light-emitting portion, the blue light-emitting element has a light-emitting area larger than that of the red light-emitting element and the green light-emitting element.

2-3. (canceled)

4. The display device according to claim 1,
wherein each of the plurality of light-emitting elements includes a first electrode, a light-emitting layer, and a second electrode in this order from the substrate side.

5. The display device according to claim 4,
wherein the light-emitting portion includes a light absorption layer in an upper layer overlying the second electrode.

6. The display device according to claim 5,
wherein at least one second light-reflecting portion is provided between the substrate and the first electrode, between the first electrode and the light-emitting layer, between the light-emitting layer and the second electrode, and between the second electrode and the light absorption layer, and
some of light generated by the light-emitting layer is reflected by the second light-reflecting portion and guided to the light-exiting portion.

7. The display device according to claim 6,
wherein the second light-reflecting portion has a refractive index lower than that of the light-emitting layer.

8. The display device according to claim 6,
wherein the second light-reflecting portion is constituted by a plurality of layers,
the plurality of layers are provided so that a refractive index decreases in order from a layer closest to the light-emitting layer to a layer farthest from the light-emitting layer, and
the layer closest to the light-emitting layer has a refractive index lower than that of the light-emitting layer.

9. The display device according to claim 6,
wherein the second light-reflecting portion includes a metal layer formed of a metal material.

10. The display device according to claim 6,
wherein the second light-reflecting portion includes a gas layer formed of a gas.

11. The display device according to claim 6,
wherein the second light-reflecting portion has unevenness on a surface facing the light-emitting layer.

12. The display device according to claim 6,
wherein the light absorption layer has unevenness on a surface on a side opposite to the light-emitting layer.

13. A display device comprising:
a substrate; and
a pixel provided on the substrate,
wherein the pixel includes
a light-emitting portion including a plurality of light-emitting elements and configured to generate light, and
a light-exiting portion adjacent to the light-emitting portion,
the light-exiting portion includes
a first light-reflecting portion provided on an incline on the substrate and configured to receive and reflect the light from the light-emitting portion, and
an opening configured to emit the light reflected by the first light-reflecting portion to the outside, and
at least some of the plurality of light-emitting elements are formed by being layered,
wherein the opening has unevenness formed by shaving a waveguide on an opening face.

14. A display device comprising:
a substrate; and
a pixel provided on the substrate,
wherein the pixel includes
a light-emitting portion including a plurality of light-emitting elements and configured to generate light, and
a light-exiting portion adjacent to the light-emitting portion,
the light-exiting portion includes
a first light-reflecting portion provided on an incline on the substrate and configured to receive and reflect the light from the light-emitting portion, and
an opening configured to emit the light reflected by the first light-reflecting portion to the outside, and
at least some of the plurality of light-emitting elements are formed by being layered,
wherein the light-exiting portion is disposed surrounding the light-emitting portion.

15. The display device according to claim 4,
wherein the opening does not overlap the light-emitting layer in a plan view.
